(19) United States
(12) Patent Application Publication
(10) Pub. No.: US 2025/0239480 A1
(43) Pub. Date: Jul. 24, 2025

(54) MEMBER FOR SEMICONDUCTOR MANUFACTURING EQUIPMENT

(71) Applicant: NGK INSULATORS, LTD., Nagoya-City (JP)

(72) Inventors: Shota YAMAKOSHI, Anpachi-Cho (JP); Masaki ISHIKAWA, Handa-Shi (JP)

(73) Assignee: NGK INSULATORS, LTD., Nagoya-City (JP)

(21) Appl. No.: 19/017,903

(22) Filed: Jan. 13, 2025

Related U.S. Application Data
(63) Continuation of application No. PCT/JP2024/002100, filed on Jan. 24, 2024.

(51) Int. Cl. H01L 21/687

(52) U.S. Cl. CPC H01L 21/68785; H01L 21/68757

(57) ABSTRACT

A member for a semiconductor manufacturing equipment includes a ceramic substrate, wherein the ceramic substrate includes an upper surface having a plurality of protrusions for placing a wafer, wherein each of the plurality of protrusions has an upper end surface, and at least one of the upper end surfaces has a patterned concave-convex shape.

### CROSS REFERENCE TO RELATED APPLICATIONS

The present invention claims the benefit of priority to International Patent Application PCT/JP2024/002100 filed on Jan. 24, 2024 with the Japanese Patent Office, the entire contents of which are incorporated herein by reference in its entirety.

### FIELD OF THE INVENTION

The present invention relates to a member for a semiconductor manufacturing equipment.

### BACKGROUND OF THE INVENTION

Conventionally, members for a semiconductor manufacturing equipment used for holding, temperature control, transporting, or the like of wafers have been known. These types of members for a semiconductor manufacturing equipment are also called a wafer placement table, an electrostatic chuck, a susceptor, or the like. Generally, they have the function of applying electrical power for electrostatic adsorption to an internal electrode and adsorbing a wafer using electrostatic force. Some members are known that have a function of controlling the temperature of the wafer by flowing gas between the wafer placement surface and the wafer, which is the object to be adsorbed.

An example of a known member for a semiconductor manufacturing equipment includes a ceramic substrate and a base plate disposed on a lower surface side of the ceramic substrate, wherein the ceramic substrate has an upper surface on which a wafer is to be placed, a lower surface and an internal electrode, and the base plate has an internal refrigerant passage. The upper surface on which a wafer is to be placed is provided with a plurality of protrusions for supporting the wafer.

Patent Literature 1 discloses that a plurality of convex portions (corresponding to “protrusions”) are formed on the substrate-facing surface (corresponding to the “upper surface on which a wafer is to be placed”) of a chuck body (corresponding to the “ceramic substrate”) formed of first ceramic particles. Patent Literature 1 discloses that a part of the convex portion excluding at least the tip end layer is formed of second ceramic particles having a major axis of 20 μm or more and 2000 μm or less, and has a porosity of 0.1% or more and 1.0% or less. Further, Patent Literature 1 discloses that the surface roughness of the tip end surface of the convex portion is 0.01 μm or less in terms of arithmetic mean roughness Ra; the tip side layer of each convex portion is a single crystal plate or polycrystalline plate that transmits light; and each convex portion, including the tip side layer, is entirely formed of second ceramic particles having a major axis of 20 μm or more and 2000 μm or less, and has a porosity of 0.1% or more and 1.0% or less, and the like.

Patent Literature 1 discloses the effects of its invention as follows:
The base side layer of each convex portion is densely formed of large ceramic particles. When the ceramic particles are large, the particle interface between the ceramic particles is wide, and when the porosity is small and the ceramic particles are dense, the bond between the ceramic particles is strong. Therefore, when dry cleaning is performed inside the plasma processing chamber using plasma, the ceramic particles constituting the base side layer can be prevented from falling off, thereby suppressing the generation of particles from the electrostatic chuck.
If the surface roughness of the tip end surface, which serves as the substrate support surface, is 0.01 μm or less in terms of arithmetic mean roughness Ra, when the substrate W is electrostatically attracted to the electrostatic chuck, damage to the convex portions due to a large force applied locally from the substrate W to the substrate support surface can be suppressed. In addition, it is also possible to suppress a change in the contact state between the convex portions and the substrate W due to damage, which would cause a change in the thermal conductivity between the substrate W and the electrostatic chuck.
When the convex portion, including the tip end surface, is formed of relatively large second ceramic particles having a major axis of 20 μm or more and 2000 μm or less, the particle interface between the ceramic particles is wide, and therefore, it is possible to suppress the falling off of the particles from the tip end surface due to contact between the tip end surface and the substrate W, or due to dry cleaning using plasma in the plasma processing chamber.

### PRIOR ART

### Patent Literature

[Patent Literature 1] Japanese Patent Application Publication No. 2023-31112

### SUMMARY OF THE INVENTION

When the wafer is in contact with the upper end surfaces of the protrusions, it may slide on the upper end surfaces of the protrusions due to thermal expansion or the like, and at this time, there is a risk that the ceramic particles that constitute the upper end surfaces of the protrusions may fall off. When ceramic particles fall off, they adhere to the wafer as particles, which can affect the quality of the semiconductor and reduce the yield. Patent Literature 1 aims to suppress the generation of particles from the electrostatic chuck by focusing on the surface roughness of the tip end surface of the protrusions (convex portions) that support the wafer, the major axis of the particles in the convex portions, and the porosity of the convex portions, but there is still room for improvement.

In view of the above circumstances, an object of an embodiment of the present invention is to provide a member for a semiconductor manufacturing equipment having a wafer placement surface that is less likely to generate particles even when a wafer slides on it.

The present inventors have conducted extensive research to solve the above problems and have created the present invention, which is exemplified as below.

### [Aspect 1]

A member for a semiconductor manufacturing equipment comprising a ceramic substrate, wherein the ceramic substrate comprises an upper surface having a plurality of protrusions for placing a wafer, wherein each of the plurality of protrusions has an upper end surface, and at least one of the upper end surfaces has a patterned concave-convex shape.

### [Aspect 2]

The member for a semiconductor manufacturing equipment according to aspect 1, wherein at least one of the upper end surfaces having the patterned concave-convex shape has a pattern composed of a plurality of streak-like convex portions extending from a center of gravity of the upper surface of the ceramic substrate toward an outer periphery.

### [Aspect 3]

The member for a semiconductor manufacturing equipment according to aspect 1, wherein at least one of the upper end surfaces having the patterned concave-convex shape has a pattern composed of a plurality of dot-like convex portions.

### [Aspect 4]

The member for a semiconductor manufacturing equipment according to aspect 1, wherein at least one of the upper end surfaces having the patterned concave-convex shape has a pattern composed of a plurality of dimples.

### [Aspect 5]

The member for a semiconductor manufacturing equipment according to aspect 1, wherein at least one of the upper end surfaces having the patterned concave-convex shape has a pattern composed of a net-like convex portion in which a plurality of linear convex portions intersect.

### [Aspect 6]

The member for a semiconductor manufacturing equipment according to any one of aspects 1 to 5, wherein the patterned concave-convex shape has a convex portion region and a concave portion region, the concave portion region has a first height, the convex portion region has a second height, the first height is lower than the second height, and wherein on at least one of the upper end surfaces, a ratio of the convex portion region to a projected area of the upper end surface is 50% or less.

### [Aspect 7]

The member for a semiconductor manufacturing equipment according to any one of aspects 1 to 6, wherein a ratio of a total projected area of the upper end surfaces of the plurality of protrusions to a projected area of the upper surface of the ceramic substrate is 3% or less.

### [Aspect 8]

A member for a semiconductor manufacturing equipment comprising a ceramic substrate, wherein the ceramic substrate comprises an upper surface for placing a wafer, the upper surface having one or more of the following patterned concave-convex shapes:
i) A pattern composed of a plurality of streak-like convex portions extending from a center of gravity of the upper surface of the ceramic substrate toward an outer periphery,
ii) A pattern composed of a plurality of dot-like convex portions,
iii) A pattern composed of a plurality of dimples,
iv) A pattern composed of a net-like convex portion in which a plurality of linear convex portions intersect.

According to the member for a semiconductor manufacturing equipment of one embodiment of the present invention, particles are unlikely to be generated even when a wafer slides on a wafer placement surface, and therefore the member for a semiconductor manufacturing equipment can contribute to improving the stability of semiconductor quality and increasing yields.

### BRIEF DESCRIPTION OF THE DRAWINGS

FIG. 1A is a schematic partial vertical cross-sectional view of a member for a semiconductor manufacturing equipment according to one embodiment of the present invention (partial cross-sectional view when cut along a plane including the central axis of the member for a semiconductor manufacturing equipment).

FIG. 1B is a schematic partial vertical cross-sectional view of a member for a semiconductor manufacturing equipment according to one embodiment of the present invention (partial cross-sectional view when cut along a plane including the central axis of the member for a semiconductor manufacturing equipment).

FIG. 2A is a schematic partial enlarged view of the vicinity of the thick frame shown in FIG. 1A.

FIG. 2B is a schematic partial enlarged view of the vicinity of the thick frame shown in FIG. 1B.

FIG. 3 is a schematic plan view of a wafer placement surface of a ceramic substrate according to one embodiment.

FIG. 4 shows an example of a patterned concave-convex shape provided on the upper end surface of a protrusion.

FIG. 5 is a manufacturing process diagram of a member for a semiconductor manufacturing equipment according to one embodiment of the present invention.

### DETAILED DESCRIPTION OF THE INVENTION

Hereinafter, embodiments of the present invention will now be described in detail with reference to the drawings. It should be understood that the present invention is not intended to be limited to the following embodiments, and any change, improvement or the like of the design may be appropriately added based on ordinary knowledge of those skilled in the art without departing from the spirit of the present invention. In addition, as used herein, “upper” and “lower” are used to conveniently express the relative positional relationship when a member for a semiconductor manufacturing equipment is placed on a horizontal plane with the upper surface of a ceramic substrate facing downward, and they do not represent any absolute positional relationships. Therefore, depending on the orientation of the member for a semiconductor manufacturing equipment, “upper” and “lower” may become “lower” and “upper”, or “left” and “right”, or “front” and “rear”.

### 1. Configuration of a Member for a Semiconductor Manufacturing Equipment

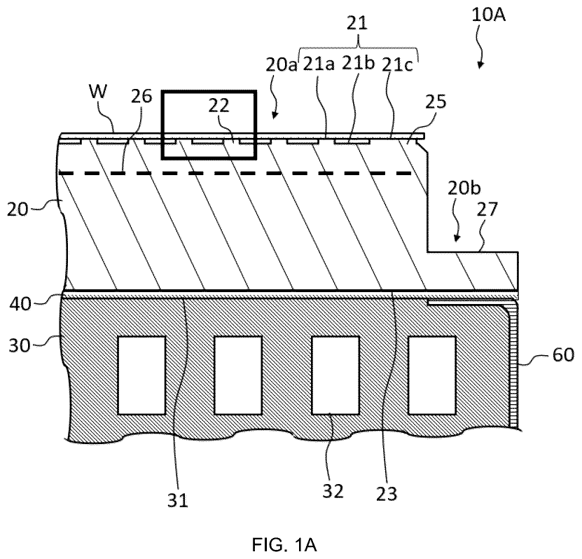

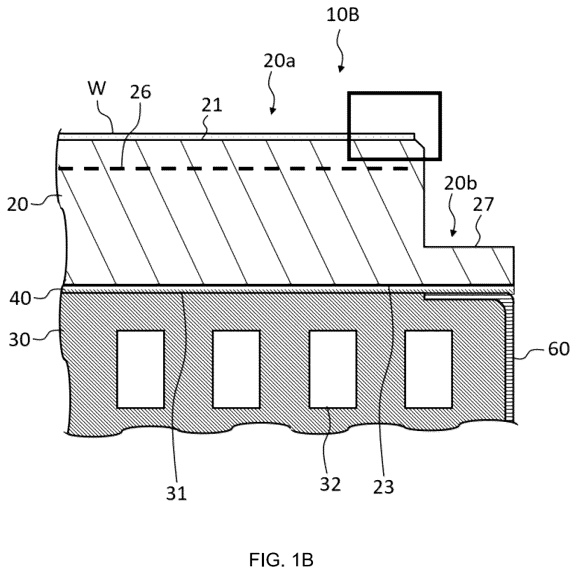

Referring to the partial vertical cross-sectional view shown in FIG. 1A, a member for a semiconductor manufacturing equipment 10A according to one embodiment of the present invention can be used when performing processes such as CVD and etching on a wafer W by utilizing plasma. The member for a semiconductor manufacturing equipment 10A comprises a ceramic substrate 20 having an upper surface 21 on which a wafer W is to be placed and a lower surface 23, with an electrode 26 provided inside the ceramic substrate 20. The member for a semiconductor manufacturing equipment 10A also comprises a base plate 30 located on the lower surface 23 side of the ceramic substrate 20, with a refrigerant passage 32 provided inside the base plate 30. The ceramic substrate 20 and the base plate 30 can be bonded via a bonding layer 40.

The ceramic substrate 20 comprises a central portion 20a having a circular upper surface 21 in a plan view, and an outer peripheral portion 20b having an annular upper surface 27 in a plan view on the outer periphery of the central portion 20a. The central portion 20a of the ceramic substrate 20 may have a diameter of, for example, 190 to 450 mm and a thickness of 1 to 5 mm. A wafer W can be placed on an upper surface 21 of the central portion 20a, and a focus ring can be placed on an upper surface 27 of the outer peripheral portion 20b. Hereinafter, the focus ring may be abbreviated as “FR”. The upper surface 27 of the outer peripheral portion 20b is one step lower than the upper surface 21 of the central portion 20a. The lower surface 23 of the central portion 20a and the outer peripheral portion 20b may be on the same plane. The illustrated ceramic substrate 20 may have the central portion 20a but may not have the outer peripheral portion 20b, that is, may not have the upper surface 27 which is one-step lower.

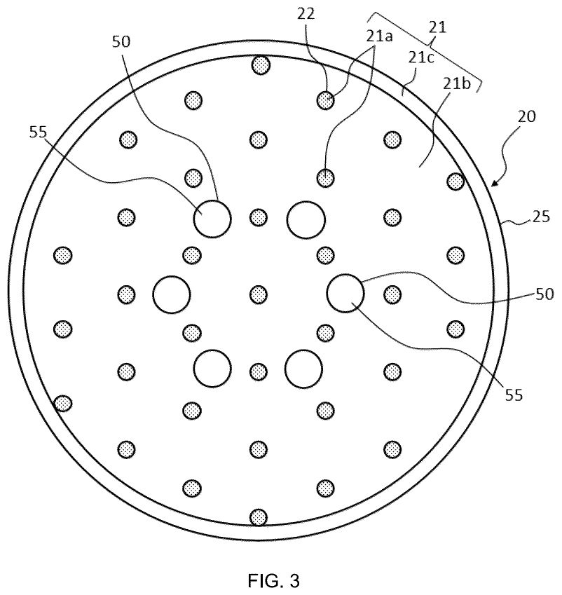

The ceramic substrate 20 has an upper surface 21 on which a wafer W is to be placed, and is provided with a plurality of protrusions 22 for placing the wafer W thereon. In addition, a seal band 25 may be formed along the outer edge of the upper surface 21. In this case, the wafer W may be supported by an upper end surface 21c of the seal band 25 and the upper end surfaces 21a of the plurality of protrusions 22. It is preferable that the seal band 25 and the plurality of protrusions 22 have the same height. As shown in FIG. 3, in one embodiment, a ring-shaped seal band 25 is formed along the outer edge of the upper surface 21 of the ceramic substrate 20, and the plurality of protrusions 22 are formed over the entire surface inside the seal band 25.

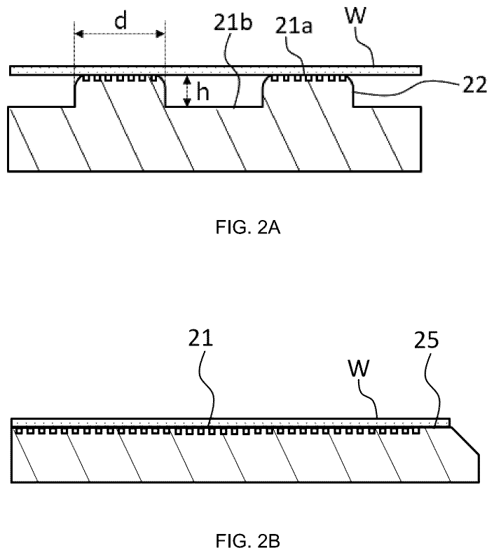

FIG. 2A is a schematic enlarged partial view of the vicinity of the thick frame shown in FIG. 1A, and shows a schematic structure of the protrusions 22 provided on the upper surface 21 of the ceramic substrate 20. The number density of the protrusions 22 per unit area in a plan view can be, for example, 1 to 150 pieces/mm², and can be 10 to 150 pieces/mm². The shape of the protrusion 22 is not limited, but may be, for example, a pillar shape such as a cylinder or a prismatic column. The height h of the protrusion 22 may be, for example, 5 to 100 μm, typically 10 to 30 μm. The diameter d of the protrusion 22 is, for example, 0.3 to 3.0 mm, and typically 0.8 to 2.2 mm. Here, the diameter d of the protrusion 22 means the equivalent circle diameter when the protrusion 22 is viewed in plan. In addition, the part of the upper surface 21 of the central portion 20a of the ceramic substrate 20 on which the seal band 25 or the protrusions 22 are not provided is referred to as a reference surface 21b.

Each of the plurality of protrusions 22 has an upper end surface 21a, and at least one of the upper end surfaces 21a, preferably 50% or more of the upper end surfaces 21a of the total number of protrusions 22, more preferably 80% or more of the upper end surfaces 21a of the total number of protrusions 22, and even more preferably the upper end surfaces 21a of all the protrusions 22 have a patterned concave-convex shape. The patterned concave-convex shape can have a convex portion region that forms the same plain as the upper end surface 21a, and a concave portion region that forms an area that is relatively lower in height than the convex portion region. Here, the convex portion region is considered to be a region that acts to come into contact with a flat wafer W when the wafer W is placed on the upper surface 21 of the ceramic substrate 20. In addition, the concave portion region refers to a region that is relatively lower in height than the convex portion region and is considered to be a region that acts such that when a flat wafer W is placed on the upper surface 21 of the ceramic substrate 20, the wafer W does not come into contact with the concave portion region. It is considered that, if the upper end surface 21a has a patterned concave-convex shape, the contact area when a wafer W comes into contact with the upper end surface 21a of the protrusion 22 is reduced, so that when the wafer W slides on the upper end surface 21a of the protrusions 22 due to thermal expansion or the like, the ceramic particles constituting the protrusions 22 are less likely to fall off, and the generation of particles is suppressed. For the same reason, it is preferable that the upper end surface 21c of the seal band 25 also have a patterned concave-convex shape.

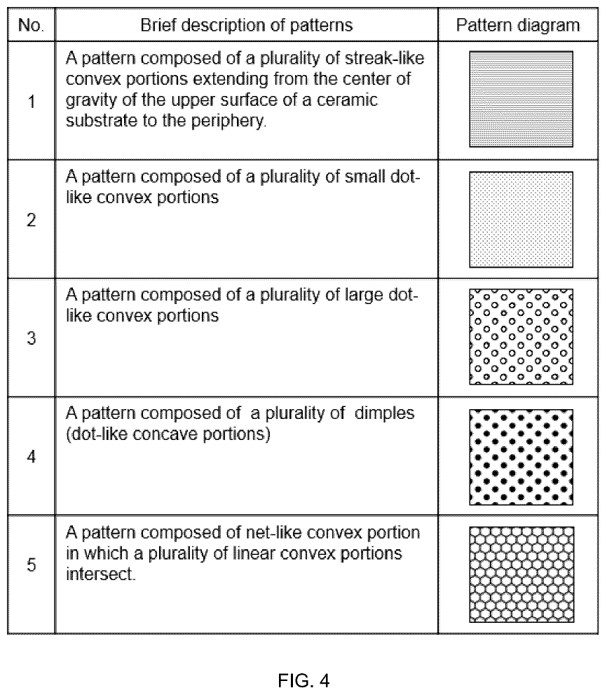

There are no particular limitations on the structure of the patterned concave-convex shape, as long as the contact area between the upper end surface 21a of the protrusions 22 and the wafer W is reduced compared to a state when the upper end surface 21a of the protrusion 22 is flat. FIG. 4 shows five specific examples of the patterned concave-convex shape when the upper end surface 21a of a protrusion 22 is seen in a plan view. The upper end surface 21c of the seal band 25 may also have the same concave-convex shape.

The concave-convex shape of No. 1 in FIG. 4 has a pattern composed of a plurality of streak-like convex portions extending from the center of gravity of the upper surface 21 of the ceramic substrate 20 toward the outer periphery. The line width of each streak-like convex portion (corresponding to the convex portion region) in a plan view can be, for example, 20 to 200 μm. When the wafer W placed on the upper surface 21 of the ceramic substrate 20 undergoes thermal expansion, the wafer W tends to slide in the radial direction. Therefore, when the upper end surface 21a of the protrusion 22 has a concave-convex shape with such a pattern, in addition to the effect of reducing the contact area with the wafer W, an additional effect of effectively reducing friction during sliding can also be obtained.

The concave-convex shape of No. 2 in FIG. 4 has a pattern composed of a plurality of dot-like convex portions. Each dot-like convex portion in No. 2 is relatively small. It is preferable that the plurality of dot-like convex portions be arranged evenly on the upper end surface 21a. The area of each dot-like convex portion (corresponding to the convex portion region) in a plan view can be, for example, 200 to 25,000 μm². When the upper end surface 21a of the protrusion 22 has a concave-convex shape with such a pattern, in addition to the effect of reducing the contact area with the wafer W, an additional effect that friction during sliding can be reduced regardless of the sliding direction of the wafer W can also be obtained.

The concave-convex shape of No. 3 in FIG. 4 also has a pattern composed of a plurality of dot-like convex portions. Each dot-like convex portion in No. 3 is relatively large. It is preferable that the plurality of dot-like convex portions be arranged evenly on the upper end surface 21a. The area of each dot-like convex portion (corresponding to the convex portion region) in a plan view can be, for example, 2000 to 250,000 μm². When the upper end surface 21a of the protrusion 22 has a concave-convex shape with such a pattern, in addition to the effect of reducing the contact area with the wafer W, an additional effect that friction during sliding can be reduced regardless of the sliding direction of the wafer W can be obtained. The concave-convex shape of No. 2 and the concave-convex shape of No. 3 are different in the area of each dot-like convex portion when viewed in a plan view.

The concave-convex shape of No. 4 in FIG. 4 has a pattern composed of a reference surface (corresponding to the convex portion region) and a plurality of dimples (dot-like concave portions) provided on the reference surface. It is preferable that the plurality of dimples be arranged evenly on the upper end surface 21a. The area of each dimple in a plan view can be, for example, 200 to 25,000 μm². When the upper end surface 21a of the protrusion 22 has a concave-convex shape with such a pattern, in addition to the effect of reducing the contact area with the wafer W, an additional effect that friction during sliding can be reduced regardless of the sliding direction of the wafer W can be obtained. In addition, it is considered that when particles fall off, the inside of the dimples serves as a refuge for the particles, making it difficult for the particles to adhere to the wafer W.

The concave-convex shape of No. 5 in FIG. 4 has a pattern composed of a net-like convex portion in which a plurality of linear convex portions (corresponding to the convex portion region) intersect. In the illustrated embodiment, each mesh of the net-like convex portion is hexagonal (honeycomb-shaped), but each mesh of the net-like convex portion may be other polygonal shapes such as triangles, quadrangles, pentagons, and octagons, or may be a combination of multiple polygonal shapes such as pentagons and triangles. The line width of each linear convex portion in a plan view can be, for example, 20 to 200 μm. The area of each mesh in a plan view can be, for example, 2,000 to 250,000 μm². When the upper end surface 21a of the protrusion 22 has a concave-convex shape with such a pattern, in addition to the effect of reducing the contact area with the wafer W, an additional effect that friction during sliding can be reduced regardless of the sliding direction of the wafer W can be obtained.

Regarding the patterned concave-convex shape on the upper end surface 21a of the plurality of protrusions 22, from the viewpoint of suppressing the falling off of the ceramic particles constituting the protrusions 22 by reducing the contact area with the wafer W, on at least one of the upper end surfaces 21a, a ratio of the convex portion region to a projected area of the upper end surface 21a is preferably 50% or less, more preferably 40% or less, and even more preferably 35% or less. On the other hand, regarding the patterned concave-convex shape on the upper end surface 21a of the plurality of protrusions 22, from the viewpoint of preventing the surface pressure from becoming too high when the wafer W is placed on the substrate, thereby suppressing the falling off of the ceramic particles, and from the viewpoint of effectively utilizing the protrusions 22, on at least one of the upper end surfaces 21a, the ratio of the convex portion region to the projected area of the upper end surface 21a is preferably 10% or more, more preferably 20% or more, and even more preferably 25% or more. Therefore, on at least one of the upper end surfaces 21a, the ratio of the convex portion region to the projected area of the upper end surface 21a is, for example, preferably 10 to 50%, more preferably 20 to 40%, and even more preferably 25 to 35%.

It is desirable that, at least one of the upper end surfaces 21a of the plurality of protrusions 22, preferably 50% or more of the upper end surfaces 21a of the total number of the protrusions 22, more preferably 80% or more of the upper end surfaces 21a of the total number of the protrusions 22, and even more preferably the upper end surfaces 21a of all the protrusions 22 each satisfy the above-mentioned area ratio for the convex portion region.

The projected area of the upper end surface 21a of the protrusion 22 is defined by an area surrounded by a region of the protrusion 22 to be measured in a plane view that protrudes above the reference surface 21b of the upper surface 21 of the ceramic substrate 20.

From the viewpoint of suppressing falling off of the ceramic particles constituting the protrusions 22 by reducing the contact area with the wafer W, it is desirable that a ratio of the total projected area of the upper end surfaces 21a of the plurality of protrusions 22 to the projected area of the upper surface 21 of the ceramic substrate 20 be small. Specifically, the ratio is preferably 3% or less, may be 2.5% or less, or may be 2% or less. On the other hand, from the viewpoint of preventing the surface pressure from becoming too high when the wafer W is placed, thereby suppressing the falling off of the ceramic particles, the ratio is preferably 0.5% or more, more preferably 0.7% or more, and even more preferably 1% or more. Therefore, the ratio of the total projected area of the upper end surfaces 21a of the plurality of protrusions 22 to the projected area of the upper surface 21 of the ceramic substrate 20 may be, for example, 0.5 to 3%, 0.7 to 2.5%, or 1 to 2%.

At least the upper end surface 21a of each of the plurality of protrusions 22 may be covered with a coating film. Examples of the coating film include a coating film containing one of more selected from silicon carbide, diamond-like carbon, amorphous silicon, molybdenum, chromium, and tantalum.

The ceramic substrate 20, including the protrusions 22 and the seal band 25, can be made of a ceramic material such as alumina or aluminum nitride. In a preferred embodiment, the ceramic particles constituting the plurality of protrusions 22 contain one or two types selected from alumina and aluminum nitride. In a more preferred embodiment, the ceramic particles constituting the plurality of protrusions 22 contain 80% by mass or more of one or two types selected from alumina and aluminum nitride. In an even more preferred embodiment, the ceramic particles constituting the plurality of protrusions 22 contain 95% by mass or more of one or two types selected from alumina and aluminum nitride.

The electrode 26 is a planar electrode used as an electrostatic electrode, and is connected to an external DC power source via a power supply member (not shown). The electrode 26 is formed of a material containing, for example, W, Mo, WC, MoC, or the like. A low-pass filter may be placed on the way of the power supply member. The power supply member is electrically insulated from the bonding layer 40 and the base plate 30. When a DC voltage is applied to this electrode 26, the wafer W is adsorbed and fixed to the wafer placement surface (specifically, the upper surface 21c of the seal band 21a and the upper surface 21a of the protrusions 22) by electrostatic attraction force, and when the application of the DC voltage is released, the adsorption and fixation of the wafer W to the wafer placement surface is released.

As the electrode 26, a heater electrode (resistance heating element) may be incorporated instead of or in addition to the electrode for electrostatic adsorption. In that case, a heater power source is connected to the heater electrode. One layer of electrode 26 may be provided inside the ceramic substrate 20, or two or more layers which are spaced apart from each other may be provided inside the ceramic substrate 20.

The base plate 30 may be, for example, a circular plate shape. The base plate 30 may have an annular flange portion on the lower surface side, which is used to clamp the member for a semiconductor manufacturing equipment 10A to a jig in the chamber. The thickness of the base plate 30 may be 20 to 40 mm, typically 25 to 35 mm. The base plate 30 is connected to a radio frequency (RF) power source and can also be used as an RF electrode.

The base plate 30 may be a circular plate (having a diameter equal to or larger than that of the ceramic substrate 20) with good electrical conductivity and thermal conductivity. Inside the base plate 30, a refrigerant passage 32 through which refrigerant circulates may be formed. The refrigerant flowing through the refrigerant passage 32 is preferably liquid and preferably electrically insulating. Examples of the electrically insulating liquid include fluorine-based inert liquids. The refrigerant passage 32 can be formed, for example, in a single stroke across the entire base plate 30 from one end (inlet) to the other end (outlet) in a plan view. A supply port and a recovery port of an external refrigerant device (not shown) are connected to the one end and the other end of the refrigerant passage 32, respectively. The refrigerant supplied from the supply port of the external refrigerant device to the one end of the refrigerant passage 32 passes through the refrigerant passage 32 and then returns from the other end of the refrigerant passage 32 to a recovery port of the external refrigerant device, and after the temperature has been adjusted, the refrigerant is again supplied to the one end of the refrigerant passage 32 from the supply port.

The base plate 30 can be made of, for example, a metal material or a composite material of metal and ceramics. Examples of the metal material include Al, Ti, Mo, W, and alloys thereof. Examples of composite materials of metal and ceramics include metal matrix composites (MMC) and ceramic matrix composites (CMC). Specific examples of such composite materials include materials containing Si, SiC, and Ti (also referred to as SiSiCTi), materials in which porous SiC is impregnated with Al and/or Si, and composite materials of Al₂O₃ and TiC. A material in which a porous SiC body is impregnated with Al is called AlSiC, and a material in which a porous SiC body is impregnated with Si is called SiSiC. It is preferable to select a material for the base plate 30 that has a coefficient of thermal expansion close to that of the material for the ceramic substrate 20. For example, when the ceramic substrate 20 is made of alumina, the base plate is preferably made of SiSiCTi or AlSiC.

As shown in FIG. 1A, the upper surface 31 of the base plate 30 is bonded to the lower surface 23 of the ceramic substrate 20 via a bonding layer 40. The bonding layer 40 bonds the lower surface 23 of the ceramic substrate 20 and the upper surface 31 of the base plate 30 together. The bonding layer 40 may be, for example, a metal layer made of solder or a metal brazing material. The bonding layer 40 is formed by, for example, TCB (thermal compression bonding). TCB is a known method in which a metal bonding material is sandwiched between two members to be bonded, and the two members are pressure bonded while being heated to a temperature below the solidus temperature of the metal bonding material. The bonding layer 40 is not limited to a metal layer. For example, a resin bonding layer may be used instead of a metal layer. The resin bonding layer can be made of, for example, a silicone resin-based adhesive, an epoxy resin-based adhesive, an acrylic resin-based adhesive, or a urethane resin-based adhesive.

At least one of the side surface of the ceramic substrate 20, the outer periphery of the bonding layer 40, and the side surface of the base plate 30 can be covered with an insulating film 60. The insulating film 60 may be, for example, a sprayed film of alumina, yttria, or the like.

In the above-described embodiment, the member for a semiconductor manufacturing equipment 10A may have a plurality of holes that pass through the member for a semiconductor manufacturing equipment 10A in a vertical direction. As such holes, a plurality of gas holes 50 opening on the upper surface 21 and lift pin holes for inserting lift pins that move the wafer W up and down relative to the upper surface 21. A plurality of gas holes 50 can be provided at appropriate positions when the upper surface 21 is seen in a plan view (see FIG. 3). A thermally conductive gas such as He gas is supplied to the gas holes 50. Normally, the gas holes 50 can be provided so as to open to a portion of the upper surface 21 on which the seal band 25 and the plurality of protrusions 22 are provided, at locations where the seal band 25 and the plurality of protrusions 22 are not provided (reference surface 21b). When the thermally conductive gas is supplied to the gas hole 50, the thermally conductive gas fills the space on the back side of the wafer W placed on the upper surface 21. A plug 55 having a gas flow passage may be embedded in the gas hole 50. A plurality of lift pin holes can be provided at equal intervals along a concentric circle of the upper surface 21 when the upper surface 21 is seen in a plan view.

### 2. How to Use a Member for a Semiconductor Manufacturing Equipment

Next, a method of using the member for a semiconductor manufacturing equipment 10A configured in this way will be exemplified. First, a wafer W is placed on the upper surface 21 of the ceramic substrate 20 with the member for a semiconductor manufacturing equipment 10A installed in a chamber (not shown). Then, the pressure inside the chamber is reduced with a vacuum pump and adjusted to the desired degree of vacuum, and a voltage is applied to the electrodes 26 of the ceramic substrate 20 to generate electrostatic adsorption force, and the wafer W is adsorbed and fixed to the wafer placement surface (specifically, the upper surface of the seal band 21c or the upper surface of the small protrusion 21a).

Next, the inside of the chamber is set to a reaction gas atmosphere at a predetermined pressure (for example, several tens to several hundreds of Pa), and in this state, a high frequency voltage such as an RF voltage is applied between an upper electrode (not shown) provided on the ceiling of the chamber and the base plate 30 of the member for a semiconductor manufacturing equipment 10A to generate plasma. The surface of the wafer W is processed by the generated plasma.

### 3. Manufacturing Examples of Member for a Semiconductor Manufacturing Equipment

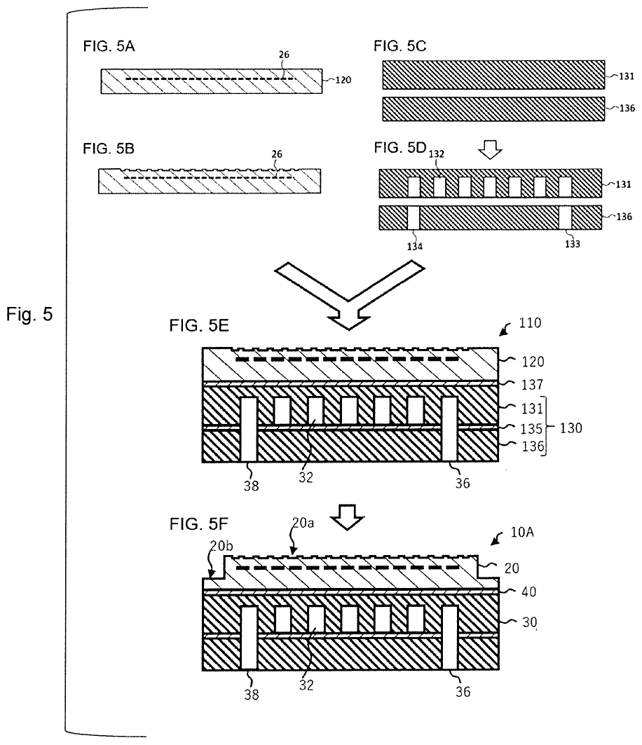

Next, a manufacturing example of the member for a semiconductor manufacturing equipment 10A will be described with reference to FIG. 5. First, a circular plate-shaped ceramic sintered body 120 that is the base of the ceramic substrate 20 is produced by hot press sintering a ceramic powder formed body (FIG. 5A). Electrodes 26 are provided inside the ceramic sintered body 120.

Next, a plurality of protrusions 22 are provided on the upper surface of the ceramic sintered body 120 by laser processing (FIG. 5B). A patterned concave-convex shape is formed on the upper end surface 21a of each protrusion 22 by laser processing. The timing for forming the plurality of protrusions 22 may be after the ceramic substrate 20 and the base plate 30 are bonded to each other.

In parallel with this, two MMC circular plate members 131 and 136 are prepared (FIG. 5C). Then, grooves 132 that will eventually become the refrigerant passages 32 are formed in the lower surface of the upper MMC circular plate member 131 by machining (FIG. 5D). The lower MMC circular plate member 136 is provided with a through hole 133 for introducing a refrigerant and a through hole 134 for discharging the refrigerant. When the ceramic sintered body 120 is made of alumina, the MMC circular plate members 131, 136 are preferably made of SiSiCTi or AlSiC, since the coefficient of thermal expansion of alumina is approximately the same as that of SiSiCTi or AlSiC.

The SiSiCTi circular plate member can be prepared, for example, as follows: First, silicon carbide, metallic Si, and metallic Ti are mixed together to produce a powder mixture. Next, a circular plate-shaped formed body is produced from the obtained powder mixture by uniaxial pressing, and the formed body is hot press sintered in an inert atmosphere to obtain a SiSiCTi circular plate member.

Next, a metal bonding material 135 is placed between the lower surface of the upper MMC circular plate member 131 and the upper surface of the lower MMC circular plate member 136, and a metal bonding material 137 is placed on the upper surface of the upper MMC circular plate member 131. Then, the ceramic sintered body 120 is placed on the metal bonding material 137 arranged on the upper surface of the upper MMC circular plate member 131. In this manner, a laminate 110 is obtained in which the lower MMC circular plate member 136, the metal bonding material 135, the upper MMC circular plate member 131, the metal bonding material 137, and the ceramic sintered body 120 are laminated in this order from the bottom (FIG. 5E). By pressing this laminate 110 while heating (TCB), a bonded body is obtained. The bonded body is formed by bonding a ceramic sintered body 120 to the upper surface of an MMC block 130 that is the source of the base plate 30 via a metal bonding layer. The MMC block 130 is formed by joining an upper MMC circular plate member 131 and a lower MMC circular plate member 136 via a metal joining layer. The MMC block 130 has a refrigerant passage 32, a refrigerant introduction portion 36, and a refrigerant discharge portion 38.

For example, TCB is performed as follows. That is, the laminate is pressed and bonded at a temperature equal to or lower than the solidus temperature of the metal bonding material (for example, a temperature 20° C. lower than the solidus temperature or more and no higher than the solidus temperature), and then returned to room temperature. As a result, the metal bonding material becomes a metal bonding layer. As the metal bonding material, an Al—Mg based bonding material or an Al—Si—Mg based bonding material can be used. For example, when TCB is performed using an Al—Si—Mg based bonding material, the laminate is pressurized in a heated state under a vacuum atmosphere. It is preferable to use a metal bonding material with a thickness of about 100 μm.

Next, the outer periphery of the ceramic sintered body 120 is cut to form a step, thereby forming a ceramic substrate 20 having a central portion 20a and an outer peripheral portion 20b. In this way, a member for a semiconductor manufacturing equipment 10A is obtained (FIG. 5F).

In addition, although the base plate 30 in FIG. 1A is described as an integrated component, it may have a structure in which two components are bonded with a metal bonding layer as shown in FIG. 5F, or a structure in which three or more components are bonded with a metal bonding layer. Further, when the bonding layer 40 is formed using the metal bonding material 137, the insulating film 60 can be formed on the base plate 30 by thermal spraying either before or after bonding to the ceramic substrate 20. When a resin adhesive sheet is used to form the bonding layer 40, an insulating film 60 may be formed by thermal spraying before bonding to the ceramic substrate 20 in order to prevent the resin from melting.

### 4. Other Embodiments

In the member for a semiconductor manufacturing equipment 10A according to the embodiment described above, the upper surface 21 of the ceramic substrate 20 has a plurality of protrusions 22, and the patterned concave-convex shape is formed on the upper end surfaces of the protrusions 22. However, the patterned concave-convex shape can also be formed without providing the protrusions 22. Referring to FIGS. 1B and 2B, a member for a semiconductor manufacturing equipment 10B according to an embodiment of the present invention comprises a ceramic substrate 20 having an upper surface 21 on which a wafer W is to be placed, and the upper surface 21 having a patterned concave-convex shape.

The upper surface 21 is not provided with any protrusions 22, but instead has one or more of the following patterned concave-convex shapes i) to iv).
i) A pattern composed of a plurality of streak-like convex portions extending from a center of gravity of the upper surface 21 of the ceramic substrate 20 toward an outer periphery.
ii) A pattern composed of a plurality of dot-like convex portions.
iii) A pattern composed of a plurality of dimples.
iv) A pattern composed of a net-like convex portion in which a plurality of linear convex portions intersect.

The patterned concave-convex shape can have a convex portion region that forms the same plain as the upper surface 21, and a concave portion region that forms an area that is relatively lower in height than the convex portion region. Here, the convex portion region is considered to be a region that acts to come into contact with the flat wafer W when the wafer W is placed on the upper surface 21 of the ceramic substrate 20. In addition, the concave portion region refers to a region that are relatively lower in height than the convex portion region, and is considered to be a region that acts such that when a flat wafer W is placed on the upper surface 21 of the ceramic substrate 20, the wafer W does not come into contact with the concave portion region. Since the upper surface 21 has a patterned concave-convex shape, the contact area when the wafer W comes into contact with the upper surface 21 is reduced. Therefore, it is considered that when the wafer W slides on the upper surface 21 due to thermal expansion or the like, the ceramic particles constituting the upper surface 21 are less likely to fall off, and the generation of particles is suppressed.

Regarding the patterned concave-convex shape on the upper surface 21, from the viewpoint of suppressing the falling off of the ceramic particles constituting the upper surface 21 by reducing the contact area with the wafer W, a ratio of the convex portion region on the upper surface 21 to the projected area of the upper surface 21 is preferably 50% or less, more preferably 30% or less, and even more preferably 10% or less. On the other hand, regarding the patterned concave-convex shape on the upper surface 21, from the viewpoint of preventing the surface pressure from becoming too high when the wafer W is placed on the substrate thereby suppressing the falling off of the ceramic particles, the ratio of the convex portion region on the upper surface 21 to the projected area of the upper surface 21 is preferably 3% or more, more preferably 5% or more, and even more preferably 7% or more. Therefore, the ratio of the convex portion region on the upper surface 21 to the projected area of the upper surface 21 is, for example, preferably 3 to 50%, more preferably 5 to 30%, and even more preferably 7 to 10%.
i) The pattern formed of a plurality of streak-like convex portions extending from the center of gravity of the upper surface 21 of the ceramic substrate 20 toward the outer periphery is exemplified by the concave-convex shape No. 1 in FIG. 4. The line width of each streak-like convex portion (corresponding to the convex portion region) in a plan view can be, for example, 20 to 200 μm.
ii) The pattern composed of a plurality of dot-like convex portions is exemplified by the concave-convex shapes No. 2 and No. 3 in FIG. 4. Each of the dot-like convex portions in No. 2 is relatively small. It is preferable that the plurality of dot-like convex portions be arranged evenly on the upper surface 21. The number density per unit area of the dot-like convex portions in a plan view can be, for example, 0.05 to 7 pieces/mm². Each of the dot-like convex portions in No. 3 is relatively large. It is preferable that the multiple dot-like convex portions be arranged evenly on the upper surface 21. The number density of the dot-like convex portions per unit area in a plan view can be, for example, 0.003 to 0.15 pieces/mm².
iii) A pattern composed of a plurality of dimples is exemplified by the concave-convex shape No. 4 in FIG. 4. The concave-convex shape of No. 4 has a pattern composed of a reference surface (corresponding to the convex portion region) and a plurality of dimples (dot-like concave portion portions) provided on the reference surface. It is preferable that the plurality of dimples be arranged evenly on the top surface 21. The number density of the dimples per unit area in a plan view may be, for example, 0.05 to 7 dimples/mm².
iv) A pattern composed of a net-like convex portion in which a plurality of linear convex portions (corresponding to the convex portion region) intersect is exemplified by the concave-convex shape No. 5 in FIG. 4. In the illustrated embodiment, each mesh of the net-like convex portion is hexagonal (honeycomb-shaped), but each mesh of the net-like convex portion may be other polygonal shapes such as triangles, quadrangles, pentagons, and octagons, or may be a combination of multiple polygonal shapes such as pentagons and triangles. The line width of each linear convex portion in a plan view can be, for example, 20 to 200 μm. The density of the meshes per unit area in a plan view can be, for example, 0.003 to 0.15 meshes/mm².

The member for a semiconductor manufacturing equipment 10B according to this embodiment is similar to the member for a semiconductor manufacturing equipment 10A according to the above-described embodiment except for the structure of the upper surface 21 of the ceramic substrate 20, and therefore a duplicated description will be omitted.

### DESCRIPTION OF REFERENCE NUMERALS

10A: Member for semiconductor manufacturing equipment
10B: Member for semiconductor manufacturing equipment
20: Ceramic substrate
20a: Central portion
20b: Outer peripheral portion
21: Upper surface
21a: Upper end surface
21b: Reference surface
21c: Upper end surface
22: Protrusion
23: Lower surface
25: Seal band
26: Electrode
27: Upper surface
30: Base plate
31: Upper surface
32: Refrigerant passage
36: Refrigerant introduction portion
38: Refrigerant discharge portion
40: Bonding layer
50: Gas hole
55: Plug
60: Insulating film
110: Laminate
120: Ceramic sintered body
130: MMC block
131: MMC circular plate member
132: Groove
133: Through hole
134: Through hole
135: Metal bonding material
136: Circular plate member
137: Metal bonding material
W: Wafer

1. A member for a semiconductor manufacturing equipment comprising a ceramic substrate, wherein the ceramic substrate comprises an upper surface having a plurality of protrusions for placing a wafer, wherein each of the plurality of protrusions has an upper end surface, and at least one of the upper end surfaces has a patterned concave-convex shape, and wherein at least one of the upper end surfaces having the patterned concave-convex shape has a pattern composed of a plurality of streak-like convex portions extending from a center of gravity of the upper surface of the ceramic substrate toward an outer periphery.

2. A member for a semiconductor manufacturing equipment comprising a ceramic substrate, wherein the ceramic substrate comprises an upper surface having a plurality of protrusions for placing a wafer, wherein each of the plurality of protrusions has an upper end surface, and at least one of the upper end surfaces has a patterned concave-convex shape, wherein at least one of the upper end surfaces having the patterned concave-convex shape has a pattern composed of a plurality of dimples.

3. A member for a semiconductor manufacturing equipment comprising a ceramic substrate, wherein the ceramic substrate comprises an upper surface having a plurality of protrusions for placing a wafer, wherein each of the plurality of protrusions has an upper end surface, and at least one of the upper end surfaces has a patterned concave-convex shape, wherein at least one of the upper end surfaces having the patterned concave-convex shape has a pattern composed of a net-like convex portion in which a plurality of linear convex portions intersect.

4. The member for a semiconductor manufacturing equipment according to claim 1, wherein the patterned concave-convex shape has a convex portion region and a concave portion region, the concave portion region has a first height, the convex portion region has a second height, the first height is lower than the second height, and wherein on at least one of the upper end surfaces, a ratio of the convex portion region to a projected area of the upper end surface is 50% or less.

5. The member for a semiconductor manufacturing equipment according to claim 1, wherein a ratio of a total projected area of the upper end surfaces of the plurality of protrusions to a projected area of the upper surface of the ceramic substrate is 3% or less.

6. A member for a semiconductor manufacturing equipment comprising a ceramic substrate, wherein the ceramic substrate comprises an upper surface for placing a wafer, the upper surface having one or more of the following patterned concave-convex shapes:
i) a pattern composed of a plurality of streak-like convex portions extending from a center of gravity of the upper surface of the ceramic substrate toward an outer periphery,
iii) a pattern composed of a plurality of dimples,
iv) a pattern composed of a net-like convex portion in which a plurality of linear convex portions intersect.
